(19) United States
(12) Patent Application Publication
(10) Pub. No.: US 2020/0201099 A1
(43) Pub. Date: Jun. 25, 2020

(54) DISPLAY DEVICE AND DISPAY TERMINAL

(71) Applicant: WUHAN CHINA STAR OPTOELECTRONICSSEMICONDUCTORDISPLAY TECHNOLOGYCO.,LTD, Wuhan,Hubel (CN)

(72) Inventor: Xiaoliang FENG, (US)

(21) Appl. No.: 16/466,640

(22) PCT Filed: Apr. 11, 2019
(86) PCT No.: PCT/CN2019/082174

§ 371 Date: Jun. 5, 2019

(30) Foreign Application Priority Data
Dec. 6, 2018 (CN) 201811484415.5

(51) Int. Cl. G02F 1/1333; H01L 27/32; G06K 9/00; G02F 1/133

(52) U.S. Cl. CPC G02F 1/13338; G02F 1/13306; G06K 9/00006; H01L 27/323

(57) ABSTRACT

The present disclosure provides a display device and a display terminal comprising the same. The display device comprises a first display screen, a display screen frame, and a second display screen. The display screen frame is disposed around the first display screen. The second display screen is disposed in the display screen frame. The first display screen and the second display screen can independently display content. Therefore, the display device and the display terminal of the present disclosure solve the technical problem that, in an existing display device, only a screen display area can display content, and improve screen utilization rate of the display device.

### FIELD OF INVENTION

The present disclosure elates to a field of display technology, and particularly to a display device and a display terminal.

### BACKGROUND

Most content display devices are liquid crystal display devices. A core portion of the liquid crystal display device is a screen display area formed by encapsulating liquid crystals within two glass substrates. There is a frame disposed around a peripheral edge area of the screen display area. Only the screen display area can display content.

Therefore, there is a technical problem to be solved by those skilled in the art to provide a technique for improving screen utilization rate of a display device.

### SUMMARY OF DISCLOSURE

The present disclosure provides a new display device and a new display terminal in order to solve the technical problem that, in the existing display device, only the screen display area can display content.

To solve the aforementioned technical problem, the present disclosure provides a technical solution as below:
the present disclosure provides a display device, comprising:
a first display screen;
a display screen frame, disposed around the first display screen;
a second display screen, disposed in the display screen frame;
a first driving circuit configured to independently drive the first display screen; and
a second driving circuit configured to independently drive the second display screen;
wherein one of the first display screen and the second display screen is used for displaying an input operation image, and the other is used for displaying an input operation result image.

In the display device of the present disclosure, the second display screen comprises one or more display areas.

In the display device of the present disclosure, wherein each of the one or more display areas are shaped as rectangles.

In the display device of the present disclosure, the second display screen is a liquid crystal display screen.

In the display device of the present disclosure, the second display screen is an organic light emitting diode (OLED) display screen.

In the display device of the present disclosure, the second display screen is a electronic ink screen.

The display device of the present disclosure further comprises a touch screen disposed on the second display screen.

In the display device of the present disclosure, the second display screen has a processor that controls fingerprint unlocking or sliding unlocking.

The display device of the present disclosure further comprises a function key.

In the display device of the present disclosure, the second display screen displays an image corresponding to an operation signal in response to a trigger of the function key.

The present disclosure further provides a display device, comprising:
a first display screen;
a display screen frame, disposed around the first display screen; and
a second display screen, disposed in the display screen frame.

The display device of the present disclosure further comprises:
a first driving circuit configured to independently drive the first display screen; and
a second driving circuit configured to independently drive the second display screen.

In the display device of the present disclosure, the second display screen comprises one or more display areas.

In the display device of the present disclosure, each of the one or more display areas are shaped as rectangles.

In the display device of the present disclosure, the second display screen is a liquid crystal display screen.

In the display device of the present disclosure, the second display screen is an organic light emitting diode (OLED) display screen.

In the display device of the present disclosure, the second display screen is an electronic ink screen.

In the display device of the present disclosure, one of the first display screen and the second display screen is used for displaying an input operation image, and the other is used for displaying an input operation result image.

In the display device of the present disclosure, the second display screen has a microprocessor that controls fingerprint unlocking or sliding unlocking.

The present disclosure further provides a display terminal, comprising the aforementioned display device and a master controller.

The beneficial effect of the present disclosure is as follows. The present disclosure provides a display device and a display terminal comprising the same. The display device comprises a first display screen, a display screen frame, and a second display screen. The display screen frame is disposed around the first display screen. The second display screen is disposed in the display screen frame. The first display screen and the second display screen are respectively driven by two independent driving circuits. The second display screen can independently display a content different form a content displayed by the first display screen. The content displayed by the second display screen can be used as a supplement to the content displayed by the first display screen. Therefore, the display device and the display terminal of the present disclosure solve the technical problem that, in the existing display device, only the screen display area can display content, and improve screen utilization rate of a display device.

### BRIEF DESCRIPTION OF DRAWINGS

In order to more clearly illustrate the technical solutions in the embodiments of the present disclosure or the prior art, a brief description of accompanying drawings used in the description of the embodiments of the present disclosure or the prior art will be given below. Obviously, the accompanying drawings in the following description are merely some embodiments of the present disclosure. For those skilled in the art, other drawings may be obtained from these accompanying drawings without creative labor.

FIG. 1 is a schematic diagram of a first structure of a display device according to an embodiment of the present disclosure;

FIG. 2 is a schematic diagram of a second structure of a display device according to an embodiment of the present disclosure;

FIG. 3 is a cross-section diagram of a display device according to an embodiment of the present disclosure in the A-A direction;

FIG. 4 is a schematic block diagram of a display terminal according to an embodiment of the present disclosure.

### DETAILED DESCRIPTION

The following description of various embodiments of the present disclosure with reference to the accompanying drawings is used to illustrate specific embodiments that can be practiced. Directional terms mentioned in the present disclosure, such as “above”, “below”, “front”, “rear”, “left”, “right”, “inside”, “outside”, “side”, etc., are merely used to indicate the direction of the accompanying drawings. Therefore, the directional terms are used for illustrating and understanding the present disclosure rather than limiting the present disclosure. In the figures, elements with similar structure are indicated by the same reference numerals.

The embodiments of the present disclosure can solve the technical problem that, in an existing display device, only a screen display area can display content.

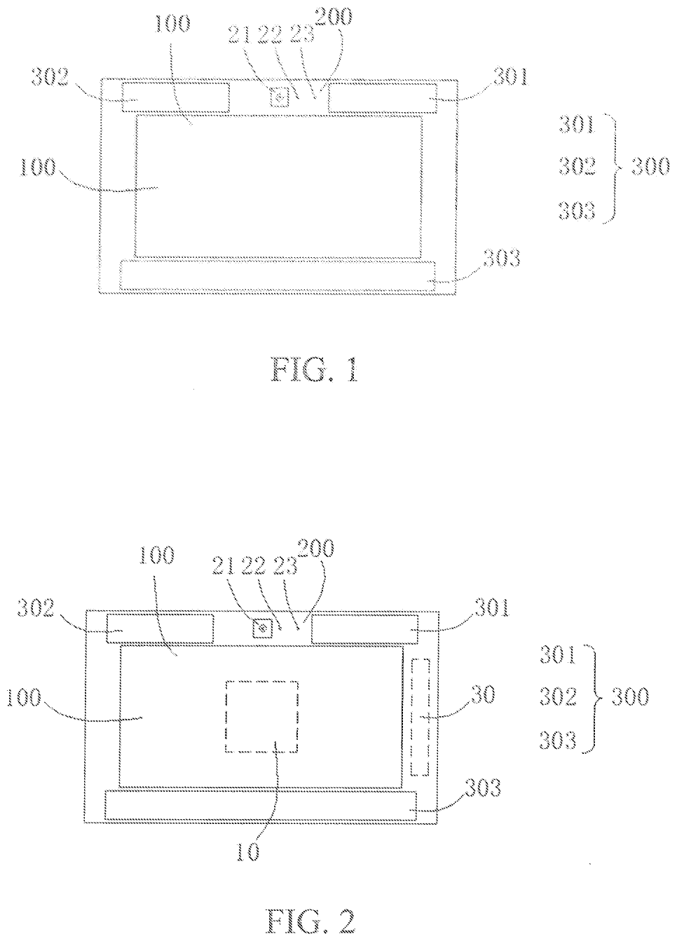

Please refer to FIG. 1, which is a schematic diagram of a first structure of a display device according to an embodiment of the present disclosure. A first display screen 100 is disposed in the central area of the display device. An area disposed around an edge of the first display screen 100 is a display screen frame 200. An upper frame of the display screen frame 200 is provided with a camera 21, a state hole 22, a microphone 23, and a second display screen 300. The second display screen 300 comprises a first display area 301, a second display area 302, and a third display area 303.

Please refer to FIG. 2, which is a schematic diagram of a second structure of a display device according to an embodiment of the present disclosure. In this embodiment, the display device further comprises a first driving circuit 10 and a second driving circuit 30, both of which are mounted in a housing of the display device. The first display screen 100 is electrically connected to the first driving circuit 10 which independently drives the first display screen 100, and the second display screen 300 is electrically connected to the second driving circuit 30 which independently drives the second display screen 300, so that the first display screen 100 and the second display screen 300 can display different images.

When the first display screen 100 is in a working state, content of the second display screen 300 can be set according to user preferences, such as lyrics, sceneries, or dynamic LOGOs, etc., which can alleviate work fatigue and relieve stress. When the first display screen 100 is in a screen-off state, the second display screen 300 can still be in a display state, such as displaying a date and time, and the like.

In an embodiment of the present disclosure, the first display area 301, the second display area 302, and the third display area 303 of the second display screen 300 mutually independently display content, so that the second display screen 300 can display more content. In addition to the first display screen 100, the camera 21, the state hole 22, and the microphone 23, the existing display device has the blank display screen frame 200. The display screen frame 200 is disposed around the edge of the first display screen 100 to form an annular structure having four corners. Therefore, when the second display screen 300 is formed as a plurality of display areas, the display screen frame 200 can be fully utilized, and the second display screen 300 can display snore content.

In practice, the second display screen 300 comprises one or more display areas. A size and number of the display area can be set according to actual needs. The display areas can display the same content, or can mutually independently display different content.

In an embodiment of the present disclosure, the display areas of the second display screen 300 are shaped as rectangles. Since the existing display screen is generally shaped as a rectangle, four frame areas of the display screen frame at the top, bottom, left, and right of the existing display screen are also shaped as rectangles. Therefore, shaping the display areas as rectangles can increase an area of the second display screen 300, thereby enabling the second display screen 300 to display more content.

It should he noted that the shape of the display areas of the second display screen 300 is not limited to a rectangle. For example, the display areas of the second display screen 300 may be other regular or irregular shapes, such as a diamond shape, an elliptical shape, and the like.

In an embodiment of the present disclosure, one of the first display screen 100 and the second display screen 300 is for displaying an input operation image, and the other display screen is for displaying an input operation result image. The content displayed by the second display screen 300 can be used as a supplement to the content displayed by the first display screen 100. For example, when adjusting brightness and sound of the first display screen 100, the adjusted levels of brightness and sound are displayed on the second display screen 300. The brightness and sound of the first display screen 100 are adjusted by an operation on the second display screen 300. Parameters of the second display screen 300 can also be displayed on the first display screen 100 and can be adjusted by an operation on the first display screen 100.

The first display screen 100 and the second display screen 300 provided by the embodiment of the present disclosure are completely separated in structures, allowing for greater freedom in selection of material types of the second display screen 300.

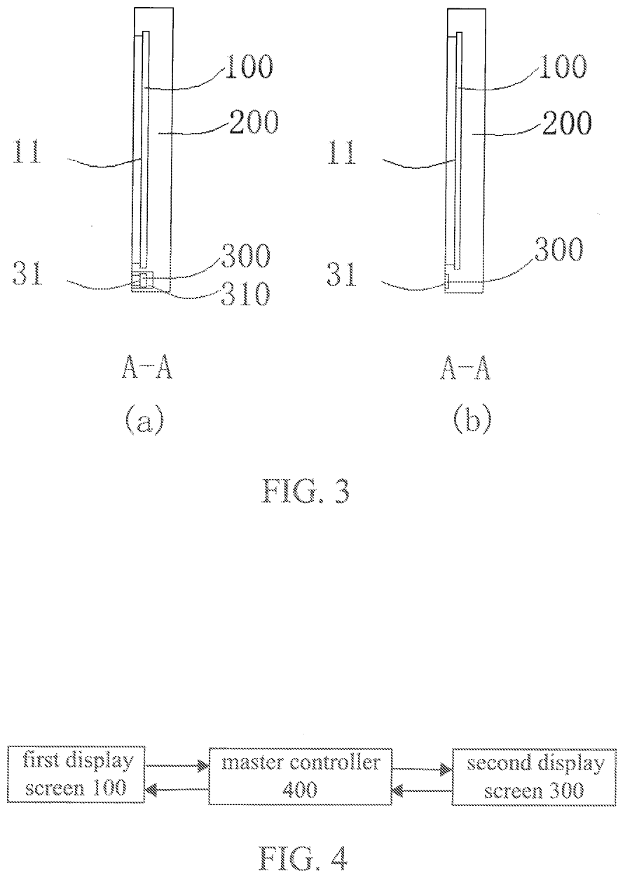

In an embodiment of the present disclosure, the second display screen 300 may be a liquid crystal display (LCD) screen comprising a backlight module, a lower polarizer, an array substrate, a liquid crystal layer, a color filter substrate, and an upper polarizer, which are sequentially stacked. Because the backlight module and the liquid crystal layer of the LCD screen need to be packaged, the LCD screen has a display screen frame. As shown in FIG. 3(a), a display screen frame 310 of the second display screen 300 is disposed inside the display screen frame 200 of the first display screen 100, and a display surface 11 of the first display screen 100 and a display surface 31 of the second display screen 300 are in the same plane.

In an embodiment of the present disclosure, the second display screen 300 may be an organic light emitting diode (OLED) display screen, comprising a base layer, an anode layer, organic layer, a conductive layer, an emission layer, and a cathode layer, which are sequentially stacked. Because OLEDs are self-illuminating, no packaging is required. Therefore, the OLED display screen has no display screen frames. As shown in FIG. 3(b), because the second display screen 300 has no display screen frames, the second display screen 300 may be disposed on the surface of the display screen frame 200, or may be disposed inside the display screen frame 200. The display surface 11 of the first display screen 100 and the display surface 31 of the second display screen 300 may be in different planes.

In an embodiment of the present disclosure, the second display screen 300 may be an electronic ink screen. The electronic ink screen is composed of two substrates coated with an electronic ink comprising numerous tiny transparent particles. The particle is formed by sealing black corpuscles with negative charges and white corpuscles with positive charges into a microcapsule having liquid inside. As an applied electric field changes, the black and white corpuscles with charges will move in different directions, making the surface of the display screen to appear black or white. Because the electronic ink screen has no backlight modules and requires power only when a page is turned, the display device provided by the embodiment of the present disclosure has low power consumption. At the same time, because the electronic ink screen has characteristics of no flickers, no radiation, and wide viewing angles, it has less damage to the eyes. Therefore, the second display screen 300 can reduce eye fatigue when used for a long time.

In an embodiment of the present disclosure, the second display screen 300 has a microprocessor that controls fingerprint unlocking or sliding unlocking, and is provided with a touch screen and a sensor. When a finger touches a graphical button on the touch screen and performs a touch or slide operation, the sensor transmits a corresponding signal to the microprocessor and the microprocessor controls the second display screen 300 to unlock.

The display device further comprises function keys, such as a brightness adjustment button, a volume adjustment button, and other function keys. When the brightness adjustment button is operated, the second display screen 300 darkens or brightens according to an operation selection. When the volume adjustment button is operated, the volume of the second display screen 300 becomes larger or smaller according to an operation selection. When other function keys are operated, the second display screen 300 displays a corresponding image.

FIG. 4 is a schematic block diagram of a display terminal according to an embodiment of the present disclosure. All display tasks of the second display screen 300 can be set in the first display screen 100 by a master controller 400, and display tasks of the first display screen 100 can also be set in the second display screen 300 by the master controller 400.

Specifically, when the first display screen 100 is enabled, the first display screen 100 transmits a signal to the master controller 400, and the master controller 400 controls the second display screen 300 to display parameter setting commands of the first display screen 100. Furthermore, when the parameter setting commands on the second display screen 300 are operated, the second display screen 300 transmits corresponding signals to the master controller 400, and then the master controller 400 feeds back the corresponding signals to the second display screen 300, causing the display content of the second display screen 300 to change accordingly.

According to the above embodiment, it can be known that:

The present disclosure provides a display device and a display terminal comprising the same. The display device comprises a first display screen, a display screen frame, and a second display screen. The display screen frame is disposed around the first display screen. The second display screen is disposed in the display screen frame. The first display screen and the second display screen are mutually independent in structure and respectively driven by two independent driving circuits. The second display screen can independently display a content different form a content displayed by the first display screen. The content displayed by the second display screen can be used as a supplement to the content displayed by the first display screen. Therefore, the display device and the display terminal of the present disclosure solve the technical problem that, in an existing display device, only a screen display area can display content, and improve screen utilization rate of a display device.

In the above, the present application has been described in the above preferred embodiments, but the preferred embodiments are not intended to limit the scope of the present application, and those skilled in the art may make various modifications without departing from the scope of the present application. The scope of the present application is determined by claims.

What is claimed is:

1. A display device, comprising:
a first display screen;
a display screen frame disposed around the first display screen;
a second display screen disposed in the display screen frame;
a first driving circuit configured to independently drive the first display screen; and
a second driving circuit configured to independently drive the second display screen;
wherein one of the first display screen and the second display screen is used for displaying an input operation image, and another is used for displaying an input operation result image.

2. The display device according to claim 1, wherein the second display screen comprises one or more display areas.

3. The display device according to claim 2, wherein each of the one or more display areas are shaped as rectangles.

4. The display device according to claim 1, wherein the second display screen is a liquid crystal display screen.

5. The display device according to claim 1, wherein the second display screen is an organic light emitting diode (OLED) display screen.

6. The display device according to claim 1, wherein the second display screen is an electronic ink screen.

7. The display device according to claim 1, further comprising a touch screen disposed on the second display screen.

8. The display device according to claim 7, wherein the second display screen has a microprocessor that controls fingerprint unlocking or sliding unlocking.

9. The display device according to claim 1, further comprising a function key.

10. The display device according to claim 9, wherein the second display screen displays an image corresponding to an operation signal in response to a trigger of the function key.

11. A display device, comprising:
a first display screen;
a display screen frame disposed around the first display screen; and
a second display screen disposed in the display screen frame.

12. The display device according to claim 11, further comprising:
a first driving circuit configured to independently drive the first display screen; and
a second driving circuit configured to independently drive the second display screen.

13. The display device according to claim 11, wherein the second display screen comprises one or more display areas.

14. The display device according to claim 13, wherein each of the one or ore display areas are shaped as rectangles.

15. The display device according to claim 11, wherein the second display screen is a liquid crystal display screen.

16. The display device according to claim 11, wherein the second display screen is an organic light emitting diode (PLED) display screen.

17. The display device according to claim 11, wherein the second display screen is an electronic ink screen.

18. The display device according to claim 11, wherein one of the first display screen and the second display screen is used for displaying an input operation image, and the other is used for displaying an input operation result image.

19. The display device according to claim 11, wherein the second display screen has a microprocessor that controls fingerprint unlocking or sliding unlocking.

20. A display terminal, comprising the display device according to claim 11 and a master controller.
